(19) United States
(12) Patent Application Publication
(10) Pub. No.: US 2011/0222219 A1
(43) Pub. Date: Sep. 15, 2011

(54) ELECTRONIC DEVICE CASE, MOLD FOR MANUFACTURING THE SAME, AND MOBILE COMMUNICATIONS TERMINAL

(75) Inventors: Sang Woo BAE, Suwon (KR); Sung Eun CHO, Suwon (KR); Dae Kyu LEE, Suwon (KR); Hyun Kil NAM, Suwon (KR); Chan Gwang AN, Suwon (KR); Jae Suk SUNG, Yongin (KR); Dae Seong JEON, Suwon (KR); Dae Ki LIM, Seongnam (KR); Chang Mok HAN, Cheonan (KR); Hyun Do PARK, Yongin (KR)

(73) Assignee: SAMSUNG ELECTRO-MECHANICS CO., LTD., Suwon (KR)

(21) Appl. No.: 13/038,776

(22) Filed: Mar. 2, 2011

(30) Foreign Application Priority Data
Mar. 15, 2010 (KR) 10-2010-0022826

(51) Int. Cl. B29C 45/14; H05K 5/00; B21C 3/00

(52) U.S. Cl. 361/679.01; 425/3; 425/116

(57) ABSTRACT

Provided is an electronic device case. The electronic device case includes a radiator including an antenna pattern portion transmitting or receiving a signal, and a connection terminal portion transmitting the signal to or receiving the signal from a circuit board of an electronic device, and an electronic device case frame manufactured by subjecting the radiator to injection-molding, supporting the radiator and forming an exterior of the electronic device. The antenna pattern portion includes an exposed portion exposed on the outermost edge of the electronic device case frame.

### CROSS-REFERENCE TO RELATED APPLICATIONS

This application claims the priority of Korean Patent Application No. 10-2010-0022826 filed on Mar. 15, 2010, in the Korean Intellectual Property Office, the disclosure of which is incorporated herein by reference.

### BACKGROUND OF THE INVENTION

1. Field of the Invention

The present invention relates to an electronic device case, a mold for manufacturing the same, and a mobile communications terminal, and more particularly, to an electronic device case including a radiator on the outer side thereof, a mold for manufacturing the same, and a mobile communications terminal.

2. Description of the Related Art

Mobile communications terminals that support wireless communications, such as cellular phones, PDAs, navigation devices, laptop computers and the like, are indispensable in modern society. Mobile communications terminals have been developed to support functions including CDMA, wireless LAN, GSM, DMB and the like. One of the most important components enabling those functions is an antenna.

Antennas, used for such mobile communications terminals, have advanced from external antennas, such as rod antennas or helical antennas, to internal antennas that are disposed inside terminals.

The most important aspect in developing terminal antennas is to reduce these antennas size and volume.

In order to achieve the reduction in antenna size and volume, a variety of methods have been proposed to solve the spatial limitations of antennas, one of which involves forming an antenna integrally with a device.

Here, the method of forming an antenna integrally with a device may include bonding a flexible antenna to a device by using adhesives, in-molding an antenna film by using In-mold labeling (IML), or generating and fusing an injection-molded protrusion.

However, considering reliability and space utilization, the method of bonding an antenna by simply using adhesives may be limited in use.

Furthermore, the method of in-molding an antenna film by using IML, although ensuring product reliability, is disadvantageous due to costly manufacturing processes and the occurrence of cosmetic defects.

### SUMMARY OF THE INVENTION

An aspect of the present invention provides an electronic device case, capable of realizing the highest radiation performance by having a radiator on the outermost portion thereof, and a mobile communications terminal including the same.

An aspect of the present invention also provides a mold for manufacturing the electronic device case.

An aspect of the present invention is also to reduce the occurrence of cosmetic defects by stably fixing a radiator to a mold for manufacturing an electronic device case when an electronic device case is produced in the mold.

According to an aspect of the present invention, there is provided an electronic device case including: a radiator including an antenna pattern portion transmitting or receiving a signal, and a connection terminal portion transmitting the signal to or receiving the signal from a circuit board of an electronic device; and an electronic device case frame manufactured by subjecting the radiator to injection-molding, supporting the radiator and forming an exterior of the electronic device, wherein the antenna pattern portion includes an exposed portion exposed on the outermost edge of the electronic device case frame.

The exposed portion may be formed in part of the antenna pattern portion.

The exposed portion may include at least one insertion hole serving to fix the radiator to a mold for injection-molding the electronic device case frame.

The exposed portion may be formed by bending the antenna pattern portion toward the outermost edge of the electronic device case frame in a stepped manner.

The radiator may include a connection portion connecting the antenna pattern portion with the connection terminal portion as a part of the radiator. The connection portion may be formed such that the antenna pattern portion is arranged on one side of the electronic device case frame, and the connection terminal portion is arranged on the other side of the electronic device case frame, which is opposite to the one side thereof.

The connection terminal portion may be in contact with and be supported by a radiator support portion protruding from the other side of the electronic device case frame, which is opposite to the one side on which the antenna pattern portion is arranged.

The electronic device case frame may include a coating layer on the outermost surface thereof to protect the exposed portion.

The electronic device case may further include a cover contacting one surface of the electronic device case frame and forming an exterior of a body.

According to another aspect of the present invention, there is provided a mobile communications terminal including: an electronic device case including an electronic device case frame manufactured by subjecting a radiator including an antenna pattern portion and a connection terminal portion to injection-molding, wherein the antenna pattern portion includes an exposed portion exposed on the outermost edge of the electronic device case frame; and a circuit board connected to the connection terminal portion and receiving a signal from or transmitting a signal to the radiator.

The exposed portion may be formed in part of the antenna pattern portion.

The exposed portion may include at least one insertion hole serving to fix the radiator to a mold for injection-molding the electronic device case frame.

The exposed portion may be formed by bending the antenna pattern portion toward the outermost edge of the electronic device case frame in a stepped manner.

The radiator may include a connection portion connecting the antenna pattern portion with the connection terminal portion as a part of the radiator. The connection portion may be formed such that the antenna pattern portion is arranged on one side of the electronic device case frame, and the connection terminal portion is arranged on the other side of the electronic device case frame, which is opposite to the one side thereof.

The connection terminal portion may be in contact with and is supported by a radiator support portion protruding from the other side of the electronic device case frame, which is opposite to the one side on which the antenna pattern portion is arranged.

The electronic device case frame may include a coating layer on the outermost surface thereof to protect the exposed portion.

The mobile communications terminal may further include a cover contacting one surface of the electronic device case frame and forming an exterior of a body.

According to another aspect of the present invention, there is provided a mold for manufacturing an electronic device case, the mold including: an upper mold and a lower mold receiving a radiator including an antenna pattern portion receiving and transmitting a signal, a connection terminal portion contacting a circuit board of an electronic device, and a connection portion allowing the antenna pattern portion and the connection terminal portion to be arranged in difference planes; and a resin material injection portion formed in the upper mold, the lower mold or the upper and lower molds so that, when the upper and lower molds are joined, a resin material is injected into an internal space between the upper and lower molds through the resin material injection portion and is applied to the radiator to thereby form an electronic device case. The upper mold comes into contact with the radiator so that the antenna pattern portion is exposed on the outermost edge of the electronic device case, and the electronic device case including the radiator is formed in the internal space.

The antenna pattern portion may include at least one insertion hole. The upper mold may include a coupling pin inserted into the insertion hole to fix the radiator in the internal space.

The coupling pin may be formed of a magnet.

The internal space between the upper and lower molds may receive the connection terminal portion, and a radiator support portion may be formed in the internal space to support the connection terminal portion.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic perspective view illustrating a mobile communications terminal, an electronic device, according to an exemplary embodiment of the present invention;

FIG. 2 is a perspective view illustrating an electronic device case according to another exemplary embodiment of the present invention;

FIG. 3 is a schematic perspective view illustrating a radiator provided to an electronic device case according to another exemplary embodiment of the present invention;

FIG. 4 is a schematic cross-sectional view illustrating how a mold for manufacturing an electronic device case is filled with a resin material for the manufacturing of an electronic device case, according to another exemplary embodiment of the present invention;

FIG. 5 is a schematic perspective view illustrating a mobile communications terminal employing an electronic device case, according to an exemplary embodiment of the present invention;

FIG. 6 is a schematic perspective view illustrating a mobile communications terminal adopting an electronic device case provided with a coating layer, according to another exemplary embodiment of the present invention;

FIG. 7 is a schematic perspective view illustrating a radiator provided to an electronic device case according to another exemplary embodiment of the present invention;

FIG. 8 is a schematic cross-sectional view illustrating how a mold for manufacturing an electronic device case is filled with a resin material in order to manufacture an electronic device case, according to another exemplary embodiment of the present invention;

FIG. 9 is a schematic perspective view illustrating a mobile communications terminal adopting an electronic device case, according to another exemplary embodiment of the present invention; and

FIG. 10 is a schematic perspective view illustrating a mobile communications terminal adopting an electronic device case provided with a coating layer, according to another exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. While those skilled in the art could readily devise many other varied embodiments that incorporate the teachings of the present invention through the addition, modification or deletion of elements, such embodiments may fall within the scope of the present invention.

The same or equivalent elements are referred to by the same reference numerals throughout the specification.

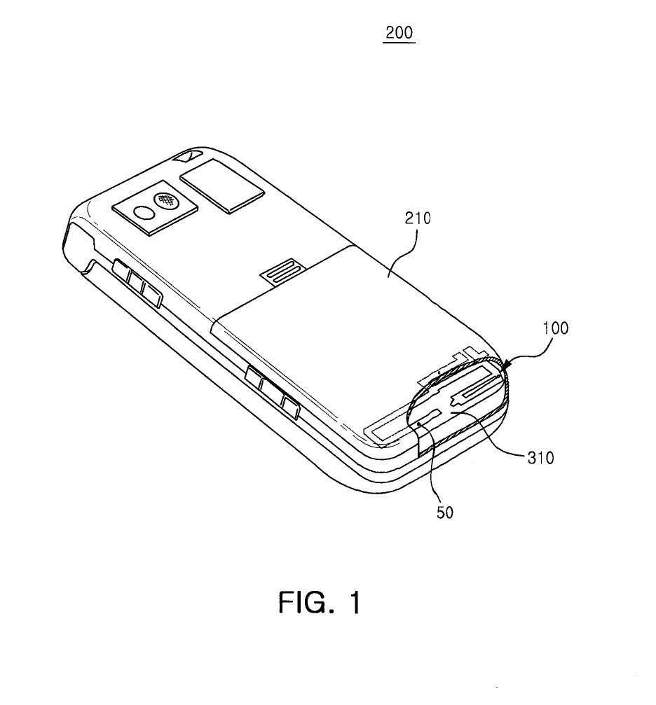

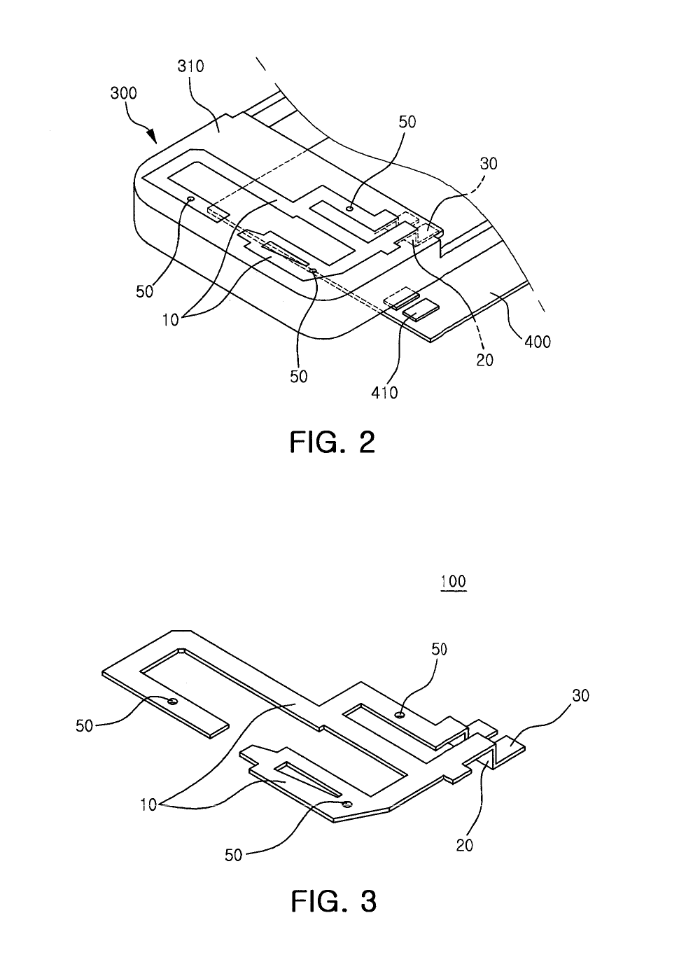

FIG. 1 is a schematic perspective view illustrating a mobile communications terminal, an electronic device according to an exemplary embodiment of the invention, and FIG. 2 is a perspective view illustrating an electronic device case according to another exemplary embodiment of the invention.

Referring to FIGS. 1 and 2, an electronic device case 300, according to an exemplary embodiment of the present invention, may be placed inside a cover 210 of a mobile communications terminal 200, and the cover 210 may be a slim cover.

Here, the cover 210 may cover not only the electronic device case 300 but also a battery 220 and prevent the mobile communications terminal 200 from being damaged by an external shock.

The electronic device case 300 may include a radiator 100 including an antenna pattern portion 10 and a connection terminal portion 30, and an electronic device case frame 310.

The connection terminal portion 30 may be connected to a terminal 410 of a circuit board 400. By this connection, the electronic device case 300 may implement antenna performance for a mobile communications terminal 200.

Furthermore, a coating layer 320 may be formed on the top surface of the electronic device case 300 in order to protect the radiator 100. However, the coating layer 320 is not an essential element in implementing the electronic device case 300 according to this exemplary embodiment of the invention.

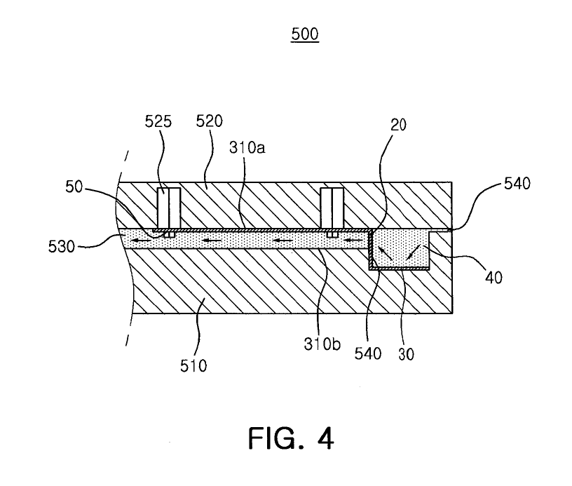

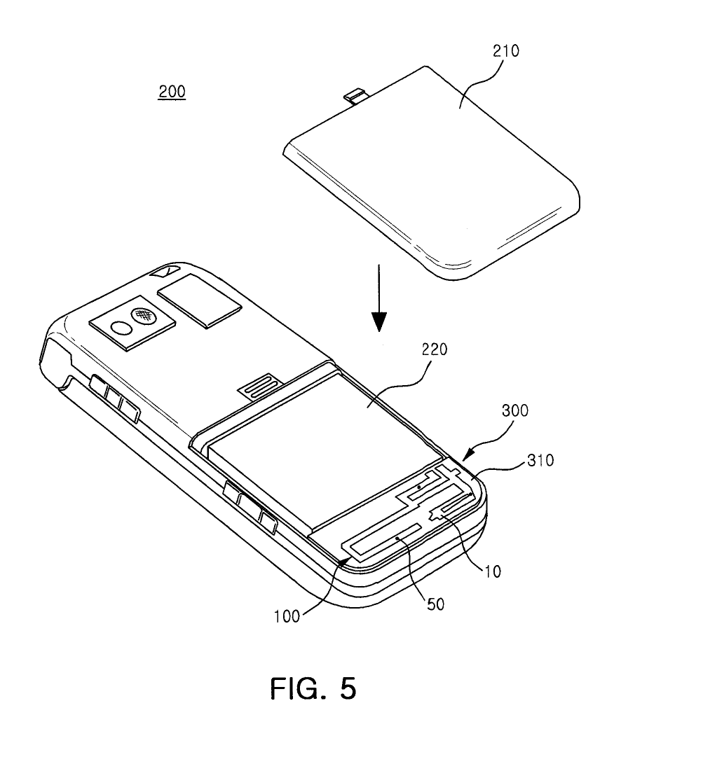

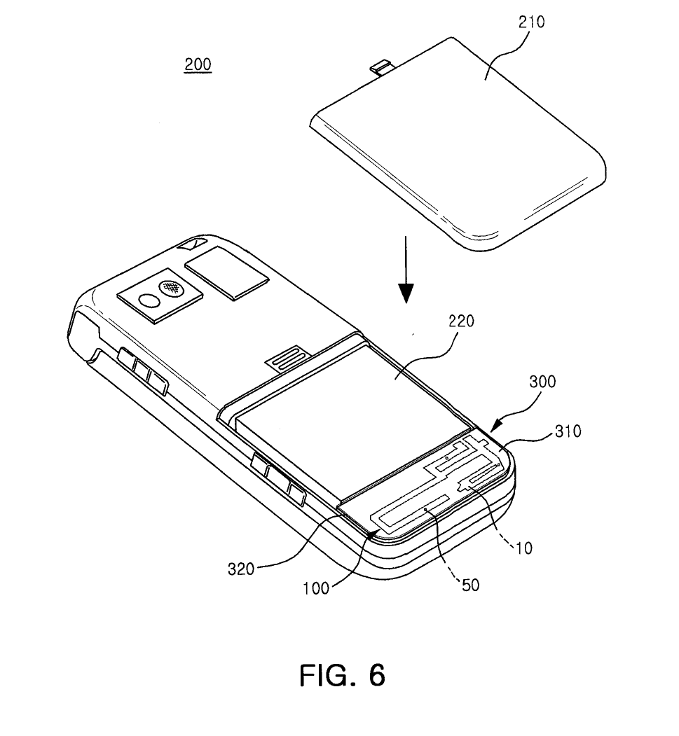

FIG. 3 is a schematic perspective view illustrating a radiator provided to an electronic device case according to another exemplary embodiment of the invention. FIG. 4 is a schematic cross-sectional view illustrating how a mold for manufacturing an electronic device case is filled with a resin material in order to manufacture an electronic device case, according to another exemplary embodiment of the invention. FIG. 5 is a schematic perspective view illustrating a mobile communications terminal adopting an electronic device case, according to an exemplary embodiment of the invention, and FIG. 6 is a schematic perspective view illustrating a mobile communications terminal including an electronic device case provided with a coating layer, according to another exemplary embodiment of the invention.

Referring to FIGS. 3, 5 and 6, the electronic device case 300, according to another exemplary embodiment of the invention, may include a radiator 100 having an antenna pattern portion 10 and a connection terminal portion 30, and an electronic device case frame 310.

The radiator 100 may be formed of a conductive material such as aluminum, copper or the like to receive an external signal and sends the received signal to a signal processor of an electronic device, such as a mobile communications terminal 200. Furthermore, the radiator 100 may have an antenna pattern portion 10 forming a meander line in order to receive external signals with various bands.

In the radiator 100, the antenna pattern portion 10 receives an external signal, and the connection terminal portion 30 is in contact with the circuit board of the electronic device to send the received external signal to the electronic device. Here, the antenna pattern portion 10 and the connection terminal portion 30 may be arranged in different planes.

In addition, the radiator 100 may have a three-dimensional structure by being bent in such a manner as to have a connection portion 20 connect the antenna pattern portion 10 and the connection terminal portion 30 to each other.

The connection portion 20 may be provided so as to position the antenna pattern portion 10 and the connection terminal portion 30 in different planes. The connection terminal portion 30, which is not embedded in the electronic device case 300, may be exposed to the opposite side 310b of the electronic device case 300 to one side 310a on which the antenna pattern portion 10 is formed.

That is, the radiator 100 may be bent such that the connection portion 20 connects the antenna pattern portion 10 with the connection terminal portion 30. In this way, the radiator 100 may have a three-dimensional curved shape.

In order to support the radiator 100 having the three-dimensional curved shape, a radiator support portion 40 may protrude from the opposite side 310b of the electronic device case frame 310.

The radiator support portion 40 may firmly support the connection portion 20 and the connection terminal portion 30 exposed to the opposite side 310b.

The connection terminal portion 30 transmits the received external signal to the electronic device. The connection terminal portions 224 may be formed by bending, forming or drawing a portion of the radiator 100.

Furthermore, the connection terminal portion 30 may be manufactured separately from the radiator 100, and then connected to the radiator 100 and connected to the terminal 410 of the circuit board 400.

Here, the antenna pattern portion 10 of the radiator 100 may have an insertion hole 50. The insertion hole 50 may serve to fix the radiator 100 to a mold 500 for injection-molding the electronic device case frame 310.

A plurality of insertion holes 50 may be provided. Provided that the insertion hole 50 can fix the radiator 100 to the mold, the number and size of insertion holes 50 is not limited.

The electronic device case frame 310, although being illustrated as having a flat portion in FIGS. 3 through 6, may have a three-dimensional structure having a flat portion and a curved portion with a curvature.

The radiator 100 may have flexibility so as to be disposed on the curved portion of the electronic device case frame 310.

The electronic device case frame 310 is an injection-molded structure. The antenna pattern portion 10 is formed on the one side 310a of the electronic device case frame 310a, while the connection terminal portion 30 may be formed on the opposite side 310b to the one side 310a thereof.

Referring to FIGS. 4 through 6, the radiator 100, after provided, may be placed in the internal space 530 within the mold 500.

The internal space 530 is created when an upper mold 520 and a lower mold 510 are joined. In detail, a recess formed in the upper mold 520 or the lower mold 510 becomes the internal space 530 when the upper and lower molds 520 and 510 are joined.

When the upper mold 520 and the lower mold 510 are joined, a coupling pin 525 formed on the upper mold 520 is inserted into the insertion hole 50 formed in the radiator 100, so that the radiator 100 can be fixed in the internal space 530.

This fixation of the radiator 100 in the internal space 530 may reduce the occurrence of defects in the exterior of the electronic device case, and allow the radiator 100 to bear a high-temperature and high-pressure injection-molding solution.

Here, the coupling pin 525 may be formed of a magnet, and this magnetic coupling pin 525 may enhance support force fixing the radiator 100.

That is, the radiator 100 placed inside the internal space 530 comes into contact with the upper mold 520 due to the coupling pin 525, and the space between the radiator 100 and the lower mold 510 is filled with a resin material.

A resin material injection hole 540 may be formed in the upper mold 520, the lower mold 510 or the upper and lower molds 520 and 510, such that the resin material can be introduced into the internal space 530 between the joined upper and lower molds 520 and 510 and applied to the radiator 100 to thereby form the electronic device case 300.

The resin material, introduced through the resin material injection hole 540, fills the space between the radiator 100 and the lower mold 510. In this way, the electronic device case 300, having the antenna pattern exposed on its outermost edge, can be manufactured.

The antenna pattern portion 10, exposed on the outermost edge, may ensure the maximum utilization of a radiation volume, thereby realizing optimum radiations.

Furthermore, a coating layer 320 may be formed on the top surface of the electronic device case 300 in order to protect the radiator 100. However, the coating layer 320 is not an essential element in implementing the electronic device case 300 according to an exemplary embodiment of the invention.

Also, the electronic device case 300 may further include a cover 210 contacting one side of the electronic device case frame 310 and forming the exterior of a body.

A radiator support portion forming recess 540 may be provided in the internal space 530 between the upper and lower molds 520 and 510. The radiator support portion forming recess 540 accommodates the connection terminal portion 30, and allows for the formation of the radiator support portion 40 supporting the connection terminal portion 30.

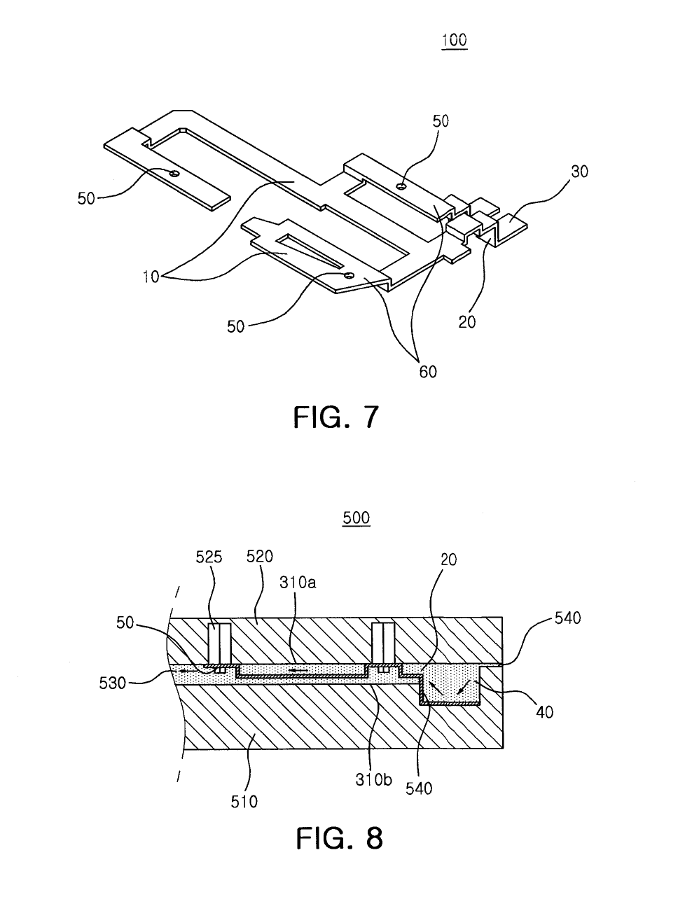

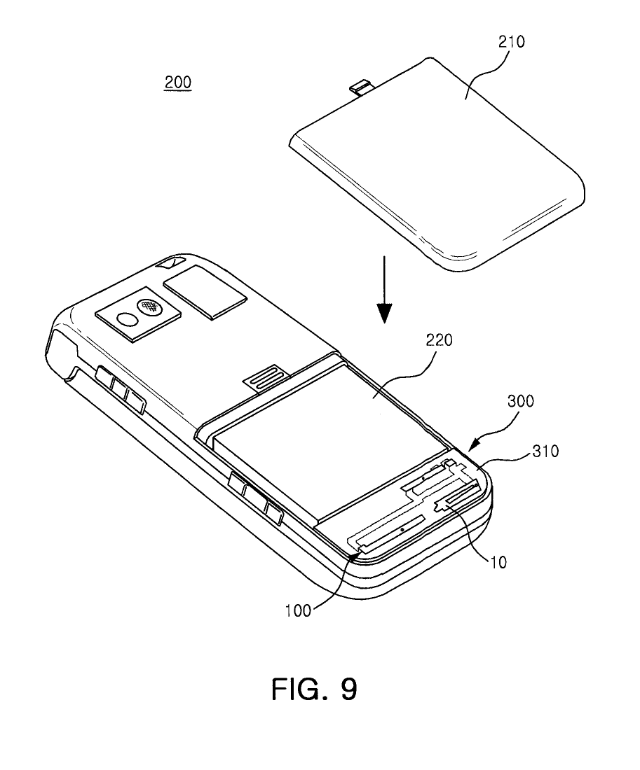

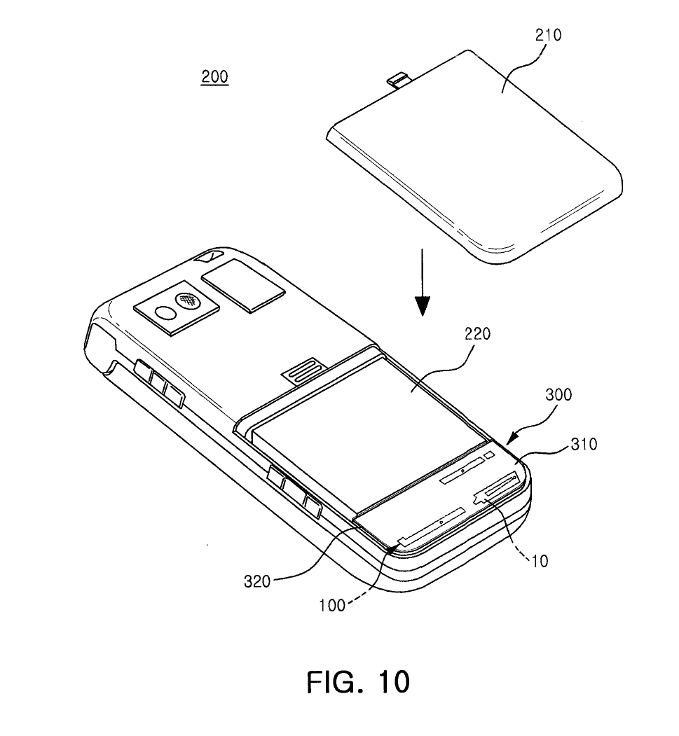

FIG. 7 is a schematic perspective view illustrating a radiator provided to an electronic device case according to another exemplary embodiment of the invention. FIG. 8 is a schematic cross-sectional view illustrating how a mold for manufacturing an electronic device case is filled with a resin material in order to manufacture an electronic device case, according to another exemplary embodiment of the invention. FIG. 9 is a schematic perspective view illustrating a mobile communications terminal adopting an electronic device case, according to another exemplary embodiment of the invention. FIG. 10 is a schematic perspective view illustrating a mobile communications terminal adopting an electronic device case provided with a coating layer, according to another exemplary embodiment of the invention.

Referring to FIGS. 7 to 10, a radiator 100 provided in the electronic device case, according to another exemplary embodiment of the invention, may include an exposed portion 60 in part of the antenna pattern portion 10.

The electronic device case according to this exemplary embodiment is identical to that of the previous embodiment, except for the exposed portion 60. Therefore, a description regarding the identical part will be omitted.

The exposed portion 60 may be formed by bending a portion of the antenna pattern portion 10 toward the outermost edge of the electronic device case frame 310 in a stepped manner. However, the formation of the exposed portion 60 is not limited only to the description, and may be changed by a person having ordinary skill in the art.

Furthermore, the exposed portion 60 is not limited in terms of the number and the area thereof.

The insertion hole 50 may be provided in the exposed portion 60. The insertion hole 50 may serve to fix the radiator 100 to the mold 500 for manufacturing the electronic device case frame 310 by injection-molding.

A plurality of insertion holes 50 may be formed, and the number and size of the insertion holes 50 are not limited, provided that they can fix the radiator 100 to the mold 500.

The coating layer 320 may be formed on the top surface of the electronic device case 300 in order to protect the radiator 100. However, the coating layer 320 is not an essential element in implementing the electronic device case 300 according to this exemplary embodiment.

The electronic device case 300 may further include the cover 210 contacting one side of the electronic device case frame 310 and forming the exterior of a body.

As described in the above exemplary embodiments, the coupling pin 525 formed in the mold 500 for manufacturing the electronic device case 300 is inserted into the insertion hole 50 formed in the antenna pattern portion 10 of the radiator 100, so that the radiator 100 comes into contact with the upper mold 520 and is fixed and supported by the internal space 530 of the Mold 500, thereby reducing the occurrence of defects in the exterior and allowing the radiator 100 to bear high-temperature and high-pressure injection-molding solution.

Since at least a part of the antenna pattern portion 10 is exposed on the outermost edge of the electronic device case frame 310, the radiation volume can be utilized to a maximum extent, and the highest radiation characteristic can be implemented.

As set forth above, according to the electronic device case, the mold for manufacturing the same and the mobile communications terminal according to exemplary embodiments of the invention, the radiator is provided on the outermost edge such that the radiation volume can be utilized to a maximum extent, thereby implementing the optimum radiation characteristics.

Furthermore, when the electronic device case is molded, the radiator is stably fixed to the internal space of the mold, thereby reducing the occurrence of defects in the exterior of the molded electronic device case, and allowing the radiator to bear a high-temperature, high-pressure injection-molding solution.

While the present invention has been shown and described in connection with the exemplary embodiments, it will be apparent to those skilled in the art that modifications and variations can be made without departing from the spirit and scope of the invention as defined by the appended claims.

What is claimed is:

1. An electronic device case comprising:
a radiator including an antenna pattern portion transmitting or receiving a signal, and a connection terminal portion transmitting the signal to or receiving the signal from a circuit board of an electronic device; and
an electronic device case frame manufactured by subjecting the radiator to injection-molding, supporting the radiator and forming an exterior of the electronic device,
wherein the antenna pattern portion includes an exposed portion exposed on the outermost edge of the electronic device case frame.

2. The electronic device case of claim 1, wherein the exposed portion is formed in part of the antenna pattern portion.

3. The electronic device case of claim 1, wherein the exposed portion has at least one insertion hole serving to fix the radiator to a mold for injection-molding the electronic device case frame.

4. The electronic device case of claim 1, wherein the exposed portion is formed by bending the antenna pattern portion toward the outermost edge of the electronic device case frame in a stepped manner.

5. The electronic device case of claim 1, wherein the radiator includes a connection portion connecting the antenna pattern portion with the connection terminal portion as a part of the radiator,
wherein the connection portion is formed such that the antenna pattern portion is arranged on one side of the electronic device case frame, and the connection terminal portion is arranged on the other side of the electronic device case frame, which is opposite to the one side thereof.

6. The electronic device case of claim 1, wherein the connection terminal portion is in contact with and is supported by a radiator support portion protruding from the other side of the electronic device case frame, which is opposite to the one side on which the antenna pattern portion is arranged.

7. The electronic device case of claim 1, wherein the electronic device case frame includes a coating layer on the outermost surface thereof to protect the exposed portion.

8. The electronic device case of claim 1, further comprising a cover contacting one surface of the electronic device case frame and forming an exterior of a body.

9. A mobile communications terminal comprising:
an electronic device case including an electronic device case frame manufactured by subjecting a radiator including an antenna pattern portion and a connection terminal portion to injection-molding, wherein the antenna pattern portion includes an exposed portion exposed on the outermost edge of the electronic device case frame; and
a circuit board connected to the connection terminal portion and receiving a signal from or transmitting a signal to the radiator.

10. The mobile communications terminal of claim 9, wherein the exposed portion is formed in part of the antenna pattern portion.

11. The mobile communications terminal of claim 9, wherein the exposed portion has at least one insertion hole serving to fix the radiator to a mold for injection-molding the electronic device case frame.

12. The mobile communications terminal of claim 9, wherein the exposed portion is formed by bending the antenna pattern portion toward the outermost edge of the electronic device case frame in a stepped manner.

13. The mobile communications terminal of claim 9, wherein the radiator includes a connection portion connecting the antenna pattern portion with the connection terminal portion as a part of the radiator,
wherein the connection portion is formed such that the antenna pattern portion is arranged on one side of the electronic device case frame, and the connection terminal portion is arranged on the other side of the electronic device case frame, which is opposite to the one side thereof.

14. The mobile communications terminal of claim 9, wherein the connection terminal portion is in contact with and is supported by a radiator support portion protruding from the other side of the electronic device case frame, which is opposite to the one side on which the antenna pattern portion is arranged.

15. The mobile communications terminal of claim 9, wherein the electronic device case frame includes a coating layer on the outermost surface thereof to protect the exposed portion.

16. The mobile communications terminal of claim 9, further comprising a cover contacting one surface of the electronic device case frame and forming an exterior of a body.

17. A mold for manufacturing an electronic device case, the mold comprising:
an upper mold and a lower mold receiving a radiator including an antenna pattern portion receiving and transmitting a signal, a connection terminal portion contacting a circuit board of an electronic device, and a connection portion allowing the antenna pattern portion and the connection terminal portion to be arranged in difference planes; and
a resin material injection portion formed in the upper mold, the lower mold or the upper and lower molds so that, when the upper and lower molds are joined, a resin material is injected into an internal space between the upper and lower molds through the resin material injection portion and is applied to the radiator to thereby form an electronic device case,
wherein the upper mold comes into contact with the radiator so that the antenna pattern portion is exposed on the outermost edge of the electronic device case, and the electronic device case including the radiator is formed in the internal space.

18. The mold of claim 17, wherein the antenna pattern portion includes at least one insertion hole,
wherein the upper mold includes a coupling pin inserted into the insertion hole to fix the radiator in the internal space.

19. The mold of claim 17, wherein the coupling pin is formed of a magnet.

20. The mold of claim 17, wherein the internal space between the upper and lower molds receives the connection terminal portion, and a radiator support portion is formed in the internal space to support the connection terminal portion.
